(19) United States
(12) Patent Application Publication
(10) Pub. No.: US 2020/0201104 A1
(43) Pub. Date: Jun. 25, 2020

(54) CURVED ELECTRONIC DEVICES

(71) Applicant: Flexenable Limited, Cambridge (GB)

(72) Inventors: William Reeves, Cambridge (GB); Sharjil Siddique, Cambridge (GB)

(21) Appl. No.: 16/718,773

(22) Filed: Dec. 18, 2019

(30) Foreign Application Priority Data
Dec. 20, 2018 (GB) 1820771.2

(51) Int. Cl. G02F 1/1333; H01L 51/00; G09F 9/30; H01L 51/52

(52) U.S. Cl. CPC G02F 1/133305; H01L 51/5246; G09F 9/301; H01L 51/0097

(57) ABSTRACT

A technique of producing an electronic device, comprising: constructing a substantially planar stack of plastics film components by a process comprising at least: applying a first plastics film component to a second plastics film component via an adhesive; thereafter manipulating the stack so as to force the first and second plastics film components out of planar configurations into stressed configurations; and, with the first and second plastics film components in the stressed configurations, treating at least parts of the adhesive to increase the cohesion of the adhesive.

### CLAIM OF PRIORITY

This application claims priority to United Kingdom Patent Application No. GB 1820771.2, filed on Dec. 20, 2018, the entire contents of which are incorporated herein by reference.

### FIELD OF THE INVENTION

Curved electronic devices having a display and/or sensing function are of increasing interest in a wide variety of fields.

The inventors for the present application have carried out extensive work on producing curved display devices.

There is hereby provided a method of producing an electronic device, comprising: constructing a substantially planar stack of plastics film components by a process comprising at least: applying a first plastics film component to a second plastics film component via an adhesive; thereafter manipulating the stack so as to force the first and second plastics film components out of planar configurations into stressed configurations; and, with the first and second plastics film components in the stressed configurations, treating at least parts of the adhesive to increase the cohesion of the adhesive.

According to one embodiment, manipulating the stack comprises bending the stack in a bending plane substantially perpendicular to the plane of the stack; and wherein the method comprises, prior to the manipulating the stack, selectively treating the adhesive at one edge portion of the stack, which one edge portion extends substantially perpendicular to the bending plane.

According to one embodiment, the method further comprises including non-adhesive spacer elements between the first and second plastics film components, which spacer elements are configured to retain a substantially uniform distance between the first and second plastics film components as the first and second plastics film components are forced into the stressed configurations.

According to one embodiment, applying the first plastics film component to the second plastics film component via the adhesive comprises applying the first plastics film component to the second plastics film component via a dispersion of the spacer elements in a liquid adhesive.

According to one embodiment, the electronics device is a display device, and forcing the first and second plastics film components into stressed configurations comprises forcibly conforming the stack to the curved surface of a transparent cover component.

According to one embodiment, the curved surface of the transparent cover component comprises a stepped region, and the method comprises: liquid coating one of more of the curved surface and the stack with an adhesive; applying the stack to the curved surface via the one or more coatings; and thereafter treating the adhesive in at least the stepped regions to increase the cohesion of the adhesive.

According to one embodiment, the first and second plastics film components have different area dimensions, such that at least one edge of the first plastics film component comes to align with a respective edge of the second plastics film component as a result of the manipulating the stack.

According to one embodiment, the stack comprises encapsulation layers on opposite sides of the stack, which encapsulation layers comprise edge portions extending beyond edges of the first and second plastics film components, and wherein the manipulating the stack comprises squeezing a portion of the adhesive out from between the first and second plastics film components, to between the edge portions of the encapsulation layers; and wherein the treating the adhesive to increase the cohesion of the adhesive comprises treating the adhesive between the edge portions.

There is also hereby provided a method of producing a liquid crystal cell device, comprising: (i) constructing a substantially planar stack of plastics film components by a process comprising at least: applying a plurality of plastics film components to each other via one or more layers of adhesive, wherein the plurality of plastics film components comprise at least two liquid crystal cell components; (ii) thereafter manipulating the stack so as to force the stack into a curved configuration in which the plastics film components are in stressed configurations; and (iii) with the plurality of plastics film components in the stressed configurations, treating at least parts of the one or more adhesive layers to increase the cohesion of the one or more adhesive layers.

According to one embodiment, the stack of plastics film components comprises a polariser component between first and second liquid crystal cell components, and the one or layers of adhesive comprise a first layer of adhesive between the polariser component and the first liquid crystal cell component, and a second layer of adhesive between the polariser component and the second liquid crystal cell component.

According to one embodiment, the at least two liquid crystal cell components each comprise an array of pixel electrodes; wherein the arrays of pixel electrodes exhibit a difference in pixel electrode pitch in the planar configuration; wherein the difference in pixel electrode pitch is calculated to produce radially aligned arrays of pixel electrodes upon the manipulating of the stack into the curved configuration.

### BRIEF DESCRIPTION OF THE FIGURES

Embodiments of the invention are described in detail, hereunder, by way of example only, with reference to the accompanying drawings, in which:

FIGS. 1A-1H illustrate an example of a lamination technique according to one embodiment of the present invention;

FIG. 2 further illustrates the bending of the stack in FIG. 1G;

FIG. 3 illustrates one variation of FIGS. 1A-Ai involving including spacer elements between the plastics film components of the stack;

FIG. 4 illustrates another variation of the technique of FIGS. 1A-1H;

FIG. 5 illustrates another variation of the technique of FIGS. 1A-1H;

FIGS. 6-8 illustrate another example of a lamination technique according to another embodiment of the present invention;

FIG. 9 illustrates one example of a plastics film component for the technique of FIGS. 1a to 1h and its variations, and for the technique of FIGS. 6-8.

### DETAILED DESCRIPTION

In one example embodiment, the technique is used for the production of an organic liquid crystal display (OLCD) device, which comprises an organic transistor device (such as an organic thin film transistor (OTFT) device) for the control component. OTFTs comprise an organic semiconductor (such as e.g. an organic polymer or small-molecule semiconductor) for the semiconductor channels.

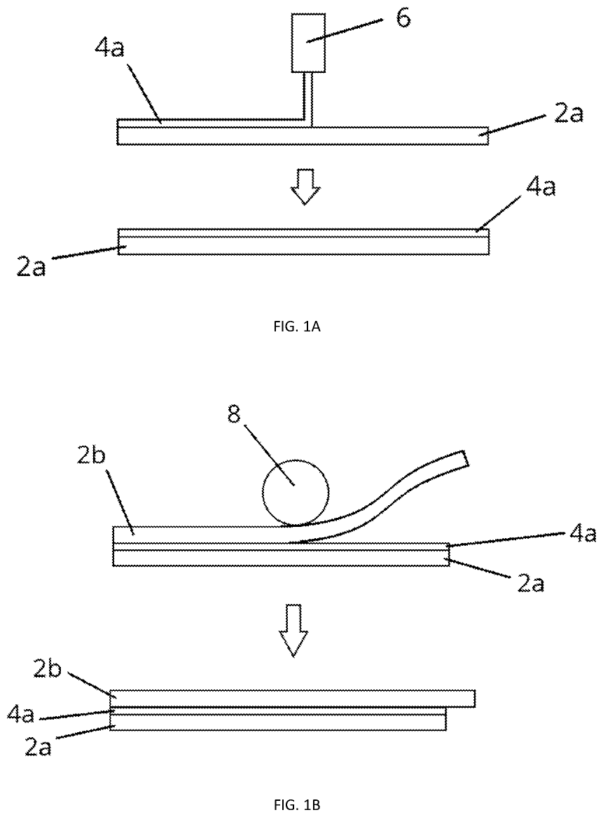

With reference to FIGS. 1A-1H, an example of a technique according to an embodiment of the invention involves assembling a stack of thin plastics film components 2a-2d for a curved electronics device. FIGS. 1A-1H show the example of an electronics device comprising four plastics film components, but the technique is equally applicable to the production of electronics devices comprising an assembly of more or less plastics film components. In the example shown in FIGS. 1A-1H, the electronics device is a touch screen display device, and the four plastics film components comprise a lower polariser component 2a, a liquid crystal (LC) cell component 2b, an upper polariser component 2c and a touch sensor component 2d. As mentioned above, the assembly may comprise additional plastics film components, such as one or more encapsulating components to better protect e.g. the LC cell component against the ingress of degrading species such as moisture and oxygen.

A plastics film component refers here to any component comprising one or more plastics films as the main structural element of the component, and includes components comprising one or more functional elements supported on one or more plastics films.

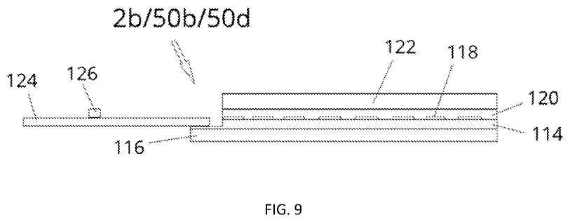

An example of the LC cell component is schematically illustrated in FIG. 9. A stack 114 of conductor, semiconductor and insulator layers is formed in situ on a plastics support film 116. The stack 114 defines an array of pixel electrodes 118, and electrical circuitry for independently controlling each pixel electrode via conductors outside the array of pixel electrodes 118. The stack 114 may, for example, define an active matrix array of thin-film transistors, including: an array of gate conductors each providing the gate electrode for a respective row of TFTs, and extending to outside the array of pixel electrodes; and an array of source conductors each providing the source electrode for a respective column of TFTs, and extending to outside the array of pixel electrodes. Each pixel electrode is associated with a respective TFT, and each TFT is associated with a unique combination of gate and source conductors, whereby each pixel electrode can be addressed independently of all other pixels.

A substantially uniform thickness of liquid crystal material 120 is contained between the array of pixel electrodes 118 and a counter component 122 comprising an array of colour filters supported on another plastics support film. A COF unit 124 is bonded to a portion of the support film 116 outside the array of pixel electrodes 118 to create a conductive connection between (i) an array of conductors (e.g. source and gate addressing conductors) defined by the stack 114 in a region outside the array of pixel electrodes 118 and (ii) a corresponding array of conductors of the COF unit, which are connected to the terminals of one or more driver chips 126 forming part of the COF unit.

With reference to FIG. 1A, the example technique begins with coating a first plastics film component 2a in its planar resting configuration with a layer of adhesive 4a using a liquid-processing technique such as e.g. slit coating, screen printing, inkjet printing, blade coating, spray coating, etc. As mentioned later, the adhesive is one whose cohesion can be increased by one or more treatments such as heating and/or exposure to some kind of electromagnetic radiation such as UV light. If an adhesive is selected for which there is a choice between irradiative and thermal treatments for increasing the cohesion, then one option involves using different treatments for the different stages of the two-stage cohesion-increasing technique described below. One example involves using an irradiative treatment for selectively increasing the cohesion of a selected portion of the adhesive, and using a thermal treatment for later increasing the cohesion of the remainder of the adhesive.

A second plastics film component 2b (also having a planar resting configuration) is then wet-laminated to the first plastics film component 2a in its planar resting configuration via the adhesive 4a, by e.g. a roller lamination technique using a lamination roller 8. The relative sizes of the two plastics film components are carefully calculated to achieve substantial alignment of all edges of the two plastics film components 2a, 2b after bending the laminated product into the desired curved configuration. In this example in which the second plastics film component is to have a greater radius of curvature than the first plastics film component in the curved product, then as shown in FIG. 1B, the second plastics film component 2b occupies a greater area than the first plastics film component 2a in the planar configuration, by an amount carefully calculated to achieve substantial alignment of all edges of the two plastics film components 2a, 2b after bending.

With reference to FIG. 1C, the processes of FIGS. 1A and 1B are repeated to produce a planar stack 10 of planar plastics film components 2a-2d with the fourth plastics film component 2d at the top of the stack 10. At this stage, the cohesion of the adhesive 4a-4c is sufficiently low that the plastics film components 2a-2d can slip relative to each other when the stack 10 is bent into the desired curved configuration. In other words, the viscosity of the adhesive 4a-4c is sufficiently low that the bending of the stack 10 into the desired configuration induces shear stress within the adhesive 4a-4c that is higher than the shear stress required to initiate slipping within the adhesive 4a-4c.

In one variation, the lamination order is reversed, by starting with the largest area plastics film component 2d (the plastics film component that is to have the highest radius of curvature in the curved product), and sequentially laminating the remaining plastics film components 2c, 2b, 2a thereto in order of size, beginning with the next largest plastics film component 2c and finishing with the smallest plastics film component 2a.

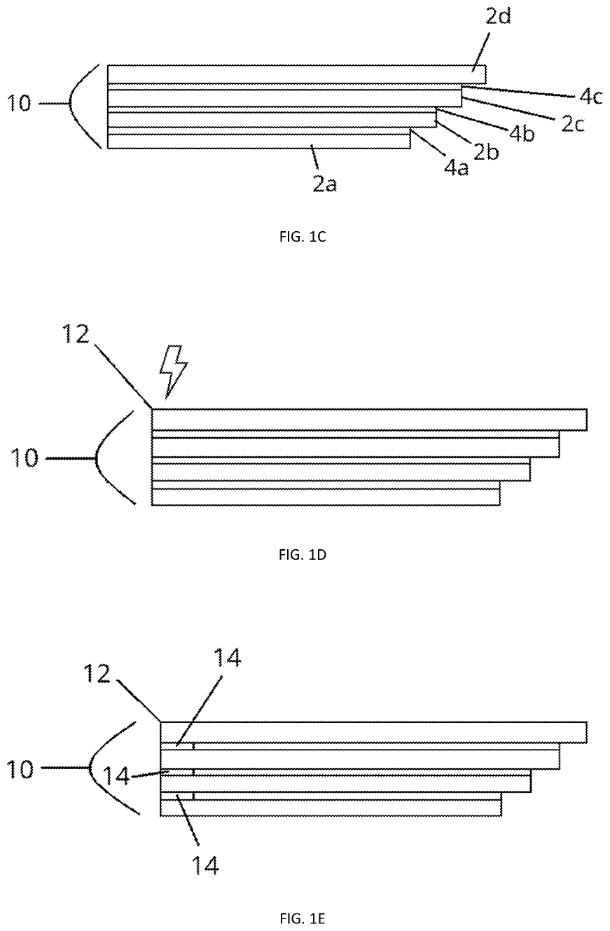

With reference to FIGS. 1D and 1E, an irradiative treatment (or alternatively, a conduction heating treatment) is used to selectively increase the cohesion of the adhesive 4a-4c in an edge portion 14 adjacent to one lateral edge 12 of the stack 10 (i.e. without treating the adhesive 4a-4c in substantially all other regions). With reference to FIG. 2, the selected edge 12 is a selected one of the two edges of the stack that is perpendicular to the bending plane for the later bending of the stack 10. With reference to the labelling in FIG. 2, where the stack lies in the xy plane and the bending plane lies in the xz plane, then the selected edge 12 extends in the y-direction. This treatment of the adhesive 4a-4c in this edge region 14 increases the viscosity of the adhesive to a level at which the shear stress required to initiate slipping within the adhesive 4a-4c is no longer lower than the shear stress induced within the adhesive 4a-4c when bending the stack into the desired curved configuration.

With reference to FIG. 1F, the upper surface of the stack 10 (surface of the fourth plastics film component 2d) is then coated with the same adhesive 4d using a liquid-processing technique such as e.g. slit coating, screen printing, inkjet printing, blade coating, spray coating, etc. Additionally, or alternatively, the inner curved surface of the transparent cover component 16 is coated with the same adhesive 4d.

With reference to FIG. 1G, the resulting stack 10a is then forcibly laminated to the inner curved surface of a transparent cover component 16 whose outer surface forms the outer surface (screen) of the display device.

This lamination may, for example, be performed using a pressing tool 9. The shear stresses induced within the adhesive by conforming the stack 10a to the curved surface of the front cover component 16 are higher than the shear stress required to initiate slipping within the adhesive layers 4a-4c outside of the treated edge region 14, but are lower than the shear stress required to initiate slipping within the adhesive layers 4a-4c in the treated edge region 14. Accordingly, there is substantially no slipping of the plastics film components 2a-2d relative to each other in the treated edge region 14 when the stack 10a is laminated to the front cover component 16, but the plastics film components 2a-2d can and do slip relative to each other outside this treated edge region 14 to produce a curved stack in which the distal edges (i.e. the edges opposite and parallel to the treated edge region 14) all align with each other. With the pressing tool 9 still in operation to forcibly hold the stack 10a in a curved configuration, a treatment is performed to increase the cohesion of the remainder of the adhesive 4a-4d. In this example, an adhesive 4a-4d is used for which there is a choice to use one or more of an irradiative treatment and a thermal treatment to increase the cohesion thereof, and a thermal treatment is used to increase the cohesion of the remainder of the adhesive. After releasing the pressing tool 9, the increased cohesion of the adhesive 4a-4d in all regions and the adhesive forces between the adhesive 4a-4d and the plastics film components 2a-2d retains the stack in the curved configuration on the front cover component 16, despite the stresses within the plastics film components 2a-2d acting to return the plastics film components 2a-2d to their planar resting configurations.

In one variation, the lamination of the stack 10a to the transparent cover component 16 is done using a lamination roller. This lamination begins from the edge 12 of the stack 10b at which the adhesive has already been pre-treated to increase its cohesion, which is referred to here as the proximal edge. Increasingly distal portions of the stack 10b are then successively laminated to the front cover component 16, and successively subjected to an irradiative treatment to increase the cohesion of the adhesive in the respective portion.

In the example described above, the treatment of the adhesive 4a-4c in the edge region 14 is done in a single step for all adhesive layers 4a-4c after all plastics film components 2a-2d are laminated to each other. According to one variation, the treatment is instead done in stages on a layer-by-layer basis after each plastics film component 2a-2d is laminated to the preceding plastics film component in the stack 10. Additionally, or alternatively, the treatment to (i) increase the cohesion of the remainder of the adhesive layers 4a-4c and (ii) increase the cohesion of the adhesive layer 4d is done in two or more stages. For example, in a first stage: the stack 10 is forcibly bent into a curved configuration (by e.g. a pressing tool) and subjected to a treatment (e.g. a thermal treatment with the pressing tool still in place) to increase the cohesion of the remainder of adhesive layers 4a-4c; and in a second stage: adhesive 4d is applied to the curved outer surface of the curved stack and/or the curved inner surface of the transparent cover component 16, the resulting curved stack is applied to the transparent cover component 16, and a treatment is then performed to increase the cohesion of the adhesive 4d between the curved stack 10a and the transparent cover component 16.

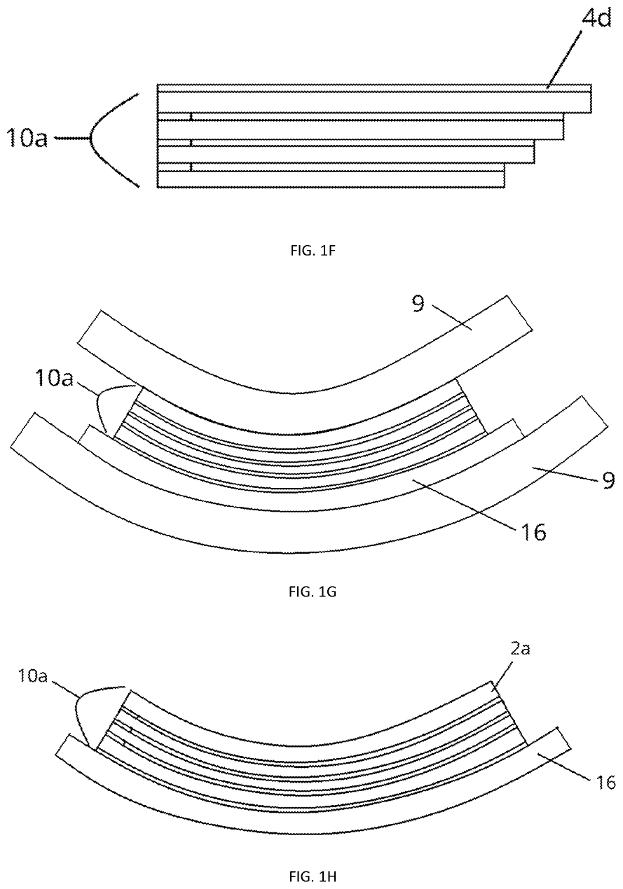

With reference to FIG. 3 (which only shows a part of the stack for conciseness), the adhesive 4a-4d may, for example, comprise a liquid dispersion of solid spacer elements 22 (e.g. spacer balls) each having substantially the same dimensions in a liquid adhesive 20. The solid spacer elements 22 serve to better achieve a uniform distance between each pair of adjacent plastics film components 2a-2d, and between the uppermost plastics film component 2d and the front cover component 16.

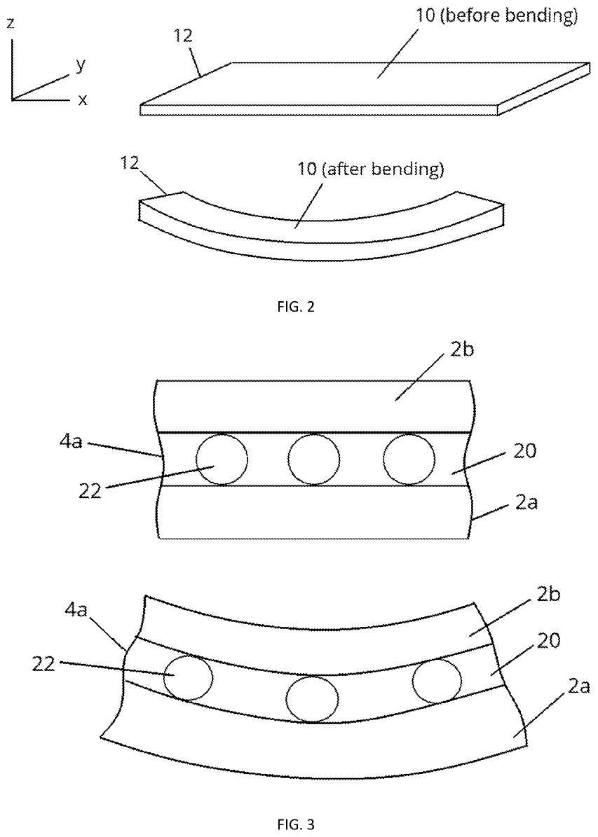

With reference to FIG. 4, another example variation involves providing oversized plastics film components 30a, 30b at the top and bottom of the stack 10. These oversized plastics film components 30a, 30b are sized so as to extend beyond all intervening plastics film components 102a, 102b (of which only two are shown in FIG. 3 for conciseness) on all four lateral sides after the stack 10 is forced into conformity with the inner curved surface of the front cover component 16. These oversized plastics film components 30a, 30b may, for example, be additional to the four plastics film components 2a-2d shown in FIGS. 1A-1H, and may function as encapsulation films protecting the inner plastics film components, such as e.g. the LC cell component, against the ingress of e.g. degrading species such as moisture and oxygen. An excess of adhesive 104a is included between each pair of adjacent plastics film components within the stack 10, and the lamination of the stack 10 to the front cover component 16 is implemented so as to squeeze a portion of the adhesive 104a out into the regions where the oversized plastics film components 30a, 30b extend beyond the inner plastics film components 102a, 102b and create a seal between the oversized plastics film components 30a, 30b on all four sides of the stack 10. Treating the adhesive to increase the cohesion of the adhesive also has the effect of further reducing the moisture and oxygen permeability of the adhesive in these lateral seal regions.

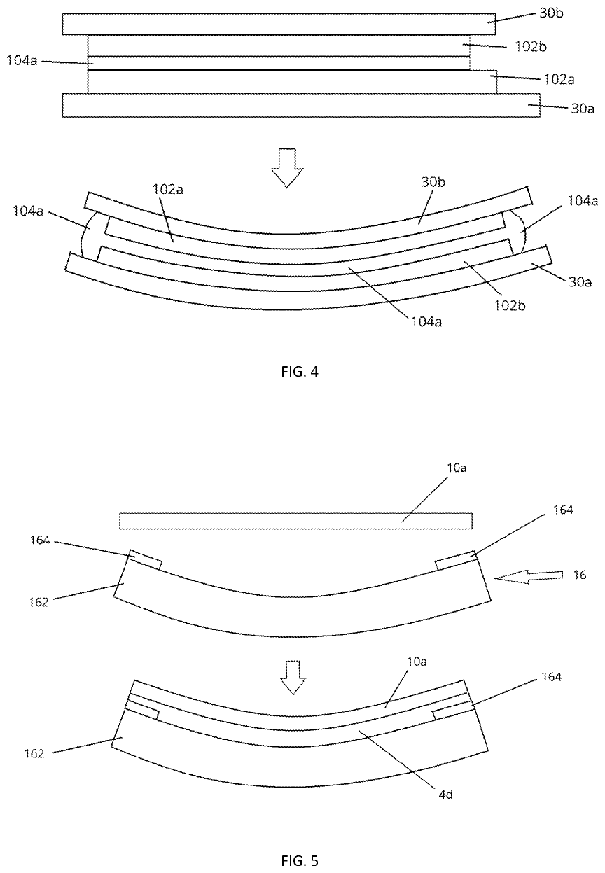

With reference to FIG. 5, the front cover component 16 may comprise an optically transmissive component 162 (such as e.g. a transparent acrylic component) and a less optically transmissive frame 164 adhered to the transmissive component at a perimeter portion of the inner curved surface of the optically transmissive component 162. This frame 164 may, for example, be produced by selectively coating the perimeter portion of the transmissive component 162 with a paint that leaves a residue that absorbs and/or scatters and/or reflects visible light more than the transmissive component 162, and thereby hide underlying portions of the stack 10 from the viewer. The addition of this frame 164 results in a stepped region at the inner curved surface of the front cover component 16. The process of using a low viscosity material for adhesive 4d better ensures that the adhesive material intimately contacts the whole of the curved inner surface in the stepped regions, even without needing to use an adhesive thickness much greater than the thickness of the frame (e.g. even when using a thickness of adhesive (after treatment to increase cohesion) less than 5 times the thickness of the frame 164/height of the step in the stepped region). Reducing the thickness of adhesive in this location can help to improve the performance of the display device, particularly when the front surface of the front cover component 16 is provided with a “matte” surface finish to reduce specular reflections at this surface.

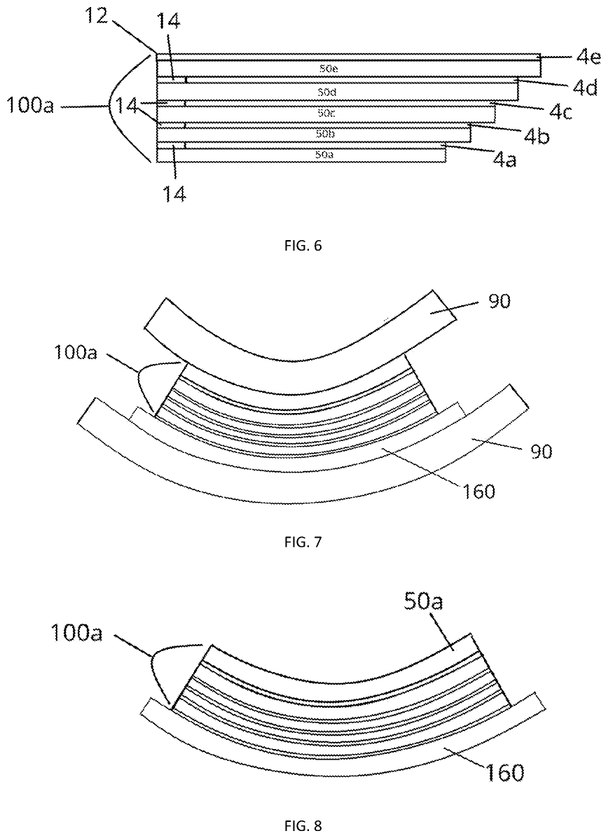

FIGS. 6-8 illustrate another example of a technique according to another embodiment of the invention. This second example involves assembling a stack of thin plastics film components 50a-50e for a curved dual-cell LC display device. The combination of two LC cells in series can improve one or more aspects of the optical output. FIGS. 6-8 show the example of a dual-cell display device comprising five plastics film components, but the technique is equally applicable to the production of dual-cell display devices comprising an assembly of a different number of plastics film components. In the example shown in FIGS. 6-8, the display device is a high contrast display device, and the five plastics film components comprise a lower polariser component 50a, a first LC cell component 50b, a middle polariser component 50c, a second LC cell component 50d and an upper polariser component 50e. The co-ordinated operation of two LC cells 50b, 50d in optical series improves the contrast of the display output. The assembly may comprise additional plastics film components, such as one or more encapsulating components to better protect e.g. the LC cell components against the ingress of degrading species such as moisture and oxygen.

Both the two LC cell components 50b, 50d may, for example, have the kind of structure shown in FIG. 9, already described above. In this example, the two LC cell components 50b, 50d differ in that only the upper LC cell component 50d includes an array of red, green and blue colour filters (e.g. as part of the counter component 122 of the upper LC cell component 50d), wherein each colour filter (red, blue or green) is associated with a respective pixel electrode of the upper LC cell component 50d. In this example, the lower LC cell component 50b does not include any array of colour filters; and each pixel electrode of the lower LC cell component 50b is associated with a respective group of red, green and blue filters of the colour filter array of the upper LC cell component 50d. Each pixel electrode of the lower LC cell component 50b is associated with a respective group of three pixel electrodes of the upper LC cell component 50d. Each LC cell component 50b, 50d may include a respective COF unit 124 as shown in FIG. 9. Alternatively, there may be conductive connections between the two LC cell components, whereby the pixel electrode arrays of both LC cell components 50b, 50d are driven via a COF unit 124 connected to one of the two LC cell components 50b, 50d.

The five plastics film components 50a-50e are stacked together in the same way as in the example of FIGS. 1A-1C via layers of adhesive 4a-4e. As in the example of FIGS. 1A-1C, the layers of adhesive 4a-4e are formed using a liquid-processing technique such as e.g. slit coating, screen printing, inkjet printing, blade coating, spray coating, etc.; and the adhesive material of each adhesive layer is a material whose cohesion can be increased by one or more treatments such as heating and/or exposure to some kind of electromagnetic radiation such as UV light.

As in the example of FIGS. 1D and 1E: before the uppermost layer of adhesive 4e is applied, an irradiative treatment (or alternatively, a conduction heating treatment) is used to selectively increase the cohesion of the adhesive 4a-4d in an edge portion 14 adjacent to one lateral edge 12 of the stack 10 (i.e. without treating the adhesive 4a-4d in substantially all other regions). With reference again to FIG. 2, the selected edge 12 is a selected one of the two edges of the stack that is perpendicular to the bending plane for the later bending of the stack 100. This treatment of the adhesive 4a-4d in this edge region 14 increases the viscosity of the adhesive to a level at which the shear stress required to initiate slipping within the adhesive 4a-4d is no longer lower than the shear stress induced within the adhesive 4a-4d when bending the stack into the desired curved configuration.

The upper surface of the stack (surface of the upper polariser component 50e) is thereafter coated with the same adhesive 4e using a liquid-processing technique such as e.g. slit coating, screen printing, inkjet printing, blade coating, spray coating, etc. Additionally, or alternatively, the inner curved surface of a transparent cover component 160 is coated with the same adhesive.

With reference to FIG. 7, the resulting stack 100a is then forcibly laminated to the inner curved surface of a transparent cover component 160 whose outer surface forms the outer surface (screen) of the display device. This lamination may, for example, be performed using a pressing tool 90. The shear stresses induced within the adhesive 4a-4e by conforming the stack 100a to the curved surface of the front cover component 160 are higher than the shear stress required to initiate slipping within the adhesive layers 4a-4e outside of the treated edge region 14, but are lower than the shear stress required to initiate slipping within the adhesive layers 4a-4d in the treated edge region 14. Accordingly, there is substantially no slipping of the plastics film components 50a-50e relative to each other in the treated edge region 14 when the stack 100a is laminated to the front cover component 160, but the plastics film components 50a-50e can and do slip relative to each other outside this treated edge region 14 to produce a curved stack. With the pressing tool 90 still in operation to forcibly hold the stack 100a in a curved configuration, a treatment is performed to increase the cohesion of the remainder of the adhesive 4a-4e. After releasing the pressing tool 90, the increased cohesion of the adhesive 4a-4e in all regions and the adhesive forces between the adhesive 4a-4e and the plastics film components 50a-50e retain the stack in the curved configuration on the front cover component 160, despite the stresses within the plastics film components 50a-50e acting to return the plastics film components 50a-50e to their planar resting configurations.

The process details, additions and variations described above for the first example are also applicable to this second example.

The pixel electrode arrays of the two LC cell components 50b, 50d are designed to take into account the difference in the radius of curvature for the two LC cell components 50b, 50d in the product, curved device. Some calculated pixel electrode pitch difference is incorporated into the pixel electrode arrays in the planar (uncurved) resting configuration, such that each set of three RGB pixel electrodes of the upper LC cell component 50d becomes radially aligned with the respective corresponding one pixel electrode of the lower LC component 50b upon bending the stack of plastics film components 50a-50e into the final curved configuration. The above-described lamination technique (involving relatively low cohesion for the adhesive 4a-4e during bending of the stack of plastics film components 50a-50e into the final curved configuration) facilitates repeatable rearrangement of the two pixel electrode arrays relative to each other upon bending of the stack of plastics film components 50a-50e into the curved configuration, and thereby facilitates the design of a reliable pixel electrode pitch difference between the pixel electrode arrays in the planar configuration.

In addition to any modifications explicitly mentioned above, it will be evident to a person skilled in the art that various other modifications of the described embodiment may be made within the scope of the invention.

The applicant hereby discloses in isolation each individual feature described herein and any combination of two or more such features, to the extent that such features or combinations are capable of being carried out based on the present specification as a whole in the light of the common general knowledge of a person skilled in the art, irrespective of whether such features or combinations of features solve any problems disclosed herein, and without limitation to the scope of the claims. The applicant indicates that aspects of the present invention may consist of any such individual feature or combination of features.

What is claimed is:

1. A method of producing an electronic device, comprising:
constructing a substantially planar stack of plastics film components by applying a first plastics film component to a second plastics film component via an adhesive;
manipulating the stack so as to force the first and second plastics film components out of planar configurations into stressed configurations; and
treating at least parts of the adhesive to increase the cohesion of the adhesive when the first and second plastics film components are in the stressed configurations.

2. The method according to claim 1, wherein manipulating the stack comprises bending the stack in a bending plane substantially perpendicular to the plane of the stack, and further comprising:
prior to the manipulating the stack, selectively treating the adhesive at one edge portion of the stack, one edge portion extending substantially perpendicular to the bending plane.

3. The method according to claim 1, further comprising including non-adhesive spacer elements between the first and second plastics film components, the non-adhesive spacer elements configured to retain a substantially uniform distance between the first and second plastics film components as the first and second plastics film components are forced into the stressed configurations.

4. The method according to claim 3, wherein applying the first plastics film component to the second plastics film component via the adhesive comprises applying the first plastics film component to the second plastics film component via a dispersion of the spacer elements in a liquid adhesive.

5. The method according to claim 1, wherein the electronics device is a display device, and wherein forcing the first and second plastics film components into stressed configurations comprises forcibly conforming the stack to the curved surface of a transparent cover component.

6. The method according to claim 5, wherein the curved surface of the transparent cover component comprises a stepped region, and further comprising:
coating one or more of the curved surfaces and the stack with an adhesive;
applying the stack to the curved surface via the one or more coatings; and
treating the adhesive in at least the stepped regions to increase the cohesion of the adhesive.

7. The method according to claim 1, wherein the first and second plastics film components have different area dimensions, such that at least one edge of the first plastics film component comes to align with a respective edge of the second plastics film component as a result of the manipulating the stack.

8. The method according to claim 1, wherein the stack comprises encapsulation layers on opposite sides of the stack, which encapsulation layers comprise edge portions extending beyond edges of the first and second plastics film components;
wherein the manipulating the stack comprises squeezing a portion of the adhesive out from between the first and second plastics film components, to between the edge portions of the encapsulation layers; and
wherein the treating the adhesive to increase the cohesion of the adhesive comprises treating the adhesive between the edge portions.

9. A method of producing a liquid crystal cell device, comprising:
constructing a substantially planar stack of plastics film components by:
applying a plurality of plastics film components to each other via one or more layers of adhesive, wherein the plurality of plastics film components comprise at least two liquid crystal cell components;
manipulating the stack so as to force the stack into a curved configuration in which the plastics film components are in stressed configurations; and
treating at least parts of the one or more adhesive layers to increase the cohesion of the one or more adhesive layers when the plurality of plastics film components are in the stressed configurations.

10. The method according to claim 9, wherein the stack of plastics film components comprises a polariser component between first and second liquid crystal cell components, and the one or layers of adhesive comprise a first layer of adhesive between the polariser component and the first liquid crystal cell component, and a second layer of adhesive between the polariser component and the second liquid crystal cell component.

11. The method according to claim 9: wherein the at least two liquid crystal cell components each comprise an array of pixel electrodes;
wherein the arrays of pixel electrodes exhibit a difference in pixel electrode pitch in the planar configuration; and
wherein the difference in pixel electrode pitch is calculated to produce radially aligned arrays of pixel electrodes upon the manipulating of the stack into the curved configuration.
